(19) United States
(12) Patent Application Publication
(10) Pub. No.: US 2023/0207284 A1
(43) Pub. Date: Jun. 29, 2023

(54) PLASMA ETCHING SYSTEM AND FARADAY SHIELDING APPARATUS WHICH CAN BE USED FOR HEATING

(71) Applicant: BEIJING LEUVEN SEMICONDUCTOR TECHNOLOGY CO. LTD, Beijing (CN)

(72) Inventors: Song GUO, Beijing (CN); Haiyang LIU, Beijing (CN); Chengyi WANG, Beijing (CN); Shiran CHENG, Beijing (CN); Xiaobo LIU, Beijing (CN); Jun ZHANG, Beijing (CN); Dongdong HU, Beijing (CN); Kaidong XU, Beijing (CN)

(21) Appl. No.: 17/927,877

(22) PCT Filed: May 27, 2021
(86) PCT No.: PCT/CN2021/096199

§ 371 Date: Nov. 26, 2022

(30) Foreign Application Priority Data
May 28, 2020 (CN) 202020935358.4

(51) Int. Cl. H01J 37/32; H05B 1/02

(52) U.S. Cl. CPC H01J 37/32651; H05B 1/023; H01J 2237/24585; H01J 2237/334; H01J 37/32119; H05B 2203/003

(57) ABSTRACT

A Faraday shielding apparatus includes a Faraday shielding plate and a heating circuit; the Faraday shielding plate includes a conductive ring and a plurality of conductive petal-shaped members radially symmetrically connected to the outer periphery of the conductive ring; when the heating circuit is used in the etching process, the Faraday shielding plate is heated by electricity. During the etching process, the heating circuit is conductively connected to the Faraday shielding plate, increasing the temperature of the Faraday shielding plate when it is energized, heating a medium window and reducing the amount of product deposits. During the cleaning process, the heating circuit and the Faraday shield are turned off, and the Faraday shielding plate is connected to a shielding power supply to clean the dielectric window. The output terminal of the heating power supply is filtered by way of a filter circuit unit, then connected to the Faraday shielding plate.

### CROSS-REFERENCE TO RELATED APPLICATION

This application claims priority to Chinese patent application NO. 202020935358.4 filed on May 28, 2020 and entitled “PLASMA ETCHING SYSTEM AND FARADAY SHIELDING APPARATUS WHICH CAN BE USED FOR HEATING”, the disclosure of which is hereby incorporated by reference in its entirety

### TECHNICAL FIELD

The present disclosure relates to the technical field of semiconductor etching technology, and in particular to a Faraday shielding apparatus which can be used for heating and a plasma etching system.

### BACKGROUND

During an etching process, voltages between different parts of a plasma coil are capacitively coupled to plasma. Although this coupling promotes ignition and stability, the part of capacitive coupling is capable of causing a local enhanced voltage in a reaction chamber, which may accelerate ions leaving the plasma to affect a dielectric window locally, resulting in local sputtering damages. In other situations, capacitive couplings may cause local depositions. Sputtering may cause damages to surface coatings on the dielectric window, and then particles may fall off and may fall on produced wafers, causing defects.

In order to solve the above-mentioned problems, a technology for heating a dielectric window in a plasma etcher as illustrated in FIG. 1 is adopted in the prior art. Main components as illustrated in FIG. 1 are radio-frequency coils 001, a dielectric window 002, a heating net 004, a heat supplying fan 005 and an external shielding cover 006. The plasma generated by the radio-frequency coils 001 passes through the dielectric window 002 for processing, and heat generated by the heating net 004 is blown to the dielectric window 002 by the heat supplying fan 005 in the direction indicated by the arrow in a schematic diagram for heating, The main disadvantages of this method are that: the heat delivered by a fan is scattered, and the heating efficiency is low; on the other hand, coils and other electrical components such as a matcher are heated at the same time, causing a high temperature and easy damages of electrical components; in order to prevent heat wind from dispersing and the temperature from getting higher and higher, which will cause high temperature damages to the operator, the external shielding cover 006 is further required, resulting in a complex structure, which will not only occupy additional space but also increase costs.

In addition, although heating a ceramic dielectric window is capable of reducing deposition amount of products, some products still deposit on the ceramic dielectric window, and after a period of time, the deposition increases to a certain amount, which still has a negative impact on the etching process. In this case, it is still necessary to disassemble the chamber and further disassemble the ceramic dielectric window for manual cleaning.

### SUMMARY

In order to solve the above-mentioned problems, the exemplary embodiments in present disclosure provide a plasma etching system and a Faraday shielding apparatus which can be used for heating thereof, in which by energizing the Faraday shielding plate in direct contact with the dielectric window to increase the temperature, the dielectric window is heated, the deposition amount of products is reduced, and the equipment structure is simplified with a high heating efficiency and a less heat loss.

Technical solutions lie in the following. Provided in the present disclosure is a Faraday shielding apparatus which can be used for heating of a plasma etching system. The apparatus includes a Faraday shielding plate, and the Faraday shielding plate includes a conductive ring and a plurality of conductive petal-shaped members radially symmetrically connected to an outer periphery of the conductive ring. The Faraday shielding apparatus further includes a heating circuit, and when the heating circuit is used in an etching process, the Faraday shielding plate is heated by electricity.

Further, the heating circuit includes a heating supply power and a filter circuit unit, an output terminal of the heating power supply is connected to the Faraday shielding plate after being filtered via the filter circuit unit.

Further, the Faraday shielding apparatus further includes a feedback control circuit, and the feedback control circuit includes a temperature measurement sensor, a temperature controller and a solid state relay. The solid state relay is arranged on the heating circuit and configured to control the heating circuit to be turned-on and turned-off. The temperature measurement sensor is configured to measure a temperature of the Faraday shielding plate and transmit data to the temperature controller. The temperature controller feeds back signals to control the turn-on and turn-off of the solid state relay according to the set temperature.

Further, the conductive ring is connected with a positive pole of the heating circuit, and an outer terminal of each of the conductive petal-shaped members is connected with a negative pole of the heating circuit or the conductive ring is connected with the negative pole of the heating circuit, and the outer terminal of each of the conductive petal-shaped members is connected with the positive pole of the healing circuit.

Further, the conductive ring includes a plurality of arc segments spaced from and insulated to each other. Each arc segment is connected with a plurality of conductive petal-shaped members. The outer terminal of one conductive petal-shaped member on one or more arc segment is connected with the positive pole of the heating circuit. An outer terminal of another conductive petal-shaped member on the arc segment is connected with the negative pole of the heating circuit.

Further, in the one arc segment, the one conductive petal-shaped member connected with the positive pole of the heating circuit and the other conductive petal-shaped member connected with the negative pole of the heating circuit are located at both ends of an arc on the arc segment, respectively.

Provided in the present disclosure is the plasma etching system. The plasma etching system includes the Faraday shielding apparatus which can be used for heating as described above.

The plasma etching system further includes a dielectric window, and the Faraday shielding plate is integrally sintered in the dielectric window

The beneficial effects of the present disclosure lie in the following. During the etching process in the present disclosure, the healing circuit is conductively connected to the Faraday shielding plate, increasing the temperature of the Faraday shielding plate when it is energized, heating the dielectric window and reducing the deposition amount of products; since the Faraday shielding plate is in direct contact with the dielectric window, the heating efficiency is high, the heat loss is less, and the equipment structure is simplified. During the cleaning process, the heating circuit and the Faraday shielding plate are turned off, and the Faraday shielding plate is applied with the shielding power supply to clean the dielectric window; the output terminal of the heating power supply is filtered via a filter circuit unit, then connected to the Faraday shielding plate, resulting in preventing couplings between the radio-frequency coils and the Faraday shielding plate effectively, which interfers with the radio frequency of the coils and the heating current of the Faraday shielding plate.

### BRIEF DESCRIPTION OF THE DRAWINGS

FIG. 1 illustrates a schematic structural diagram of a structure for heating a dielectric window in a plasma etcher in the prior art.

FIG. 2 illustrates a schematic structural diagram of the present disclosure.

FIG. 3 illustrates a schematic diagram of a Faraday shielding apparatus of the present disclosure.

FIG. 4 illustrates a process flow chart of applying the present disclosure.

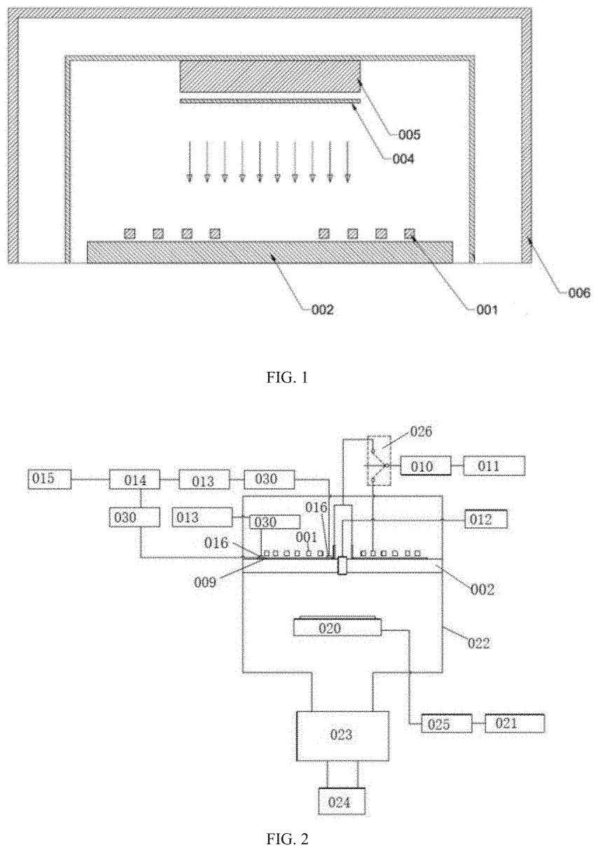

### DETAILED DESCRIPTION OF THE EMBODIMENTS

As illustrated in FIG. 2, the exemplary embodiments in present disclosure provides a plasma etching system. The system includes a reaction chamber 022, radio-frequency coils 001 and a bias electrode 020.

A dielectric window 002 is arranged above the reaction chamber 022, and the radio-frequency coils 001 are located above the dielectric window 002. The radio-frequency coils 001 are powered through an excitation radio-frequency power supply Oil after being tuned via an excitation matching network 010.

The bias electrode 020 is located inside the reaction chamber 022, which is powered through the a biasing radio-frequency power supply 021 after being tuned via a biasing matching network 025.

A vacuum pump 024 and a pressure control valve 023 are further arranged at a lower end of the reaction chamber 022, which are configured to maintain a vacuum degree required by the reaction chamber 022.

The plasma etching system further includes a gas source 012 configured to provide process gas to the reaction chamber 022, and the process gas enters the reaction chamber 022 through the dielectric window 002.

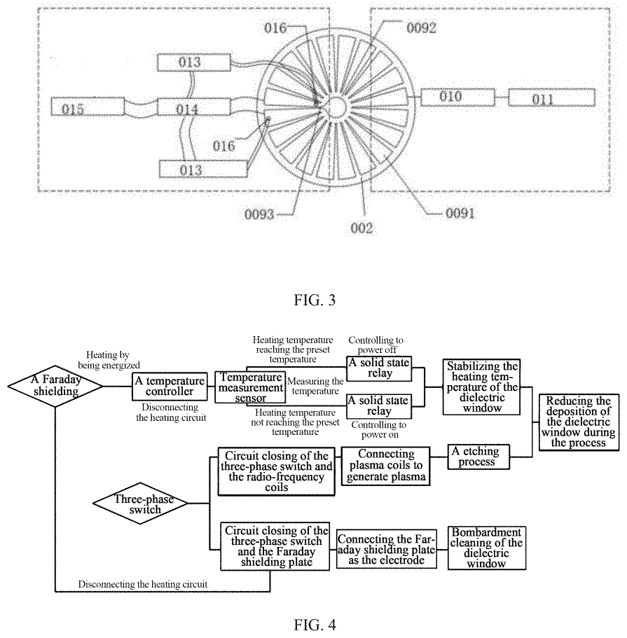

As illustrated in FIG. 3, the plasma etching system further includes a Faraday shielding apparatus which can be used for heating. The Faraday shielding apparatus includes a Faraday shielding plate 009. The Faraday shielding plate 009 includes a conductive ring 0092 and a plurality of conductive petal-shaped members 0091 radially and symmetrically connected to the outer periphery of the conductive ring 0092. In this embodiment, the Faraday shielding plate 009 is further powered through the excitation radio-frequency power supply 011 after being tuned via the excitation matching network 010, and configured to be a shielding power supply. The output terminal of the excitation matching network 010 is capable of being connected with radio-frequency coils 001 or the Faraday shielding plate 009 through a three-phase switch 026.

During the etching process, a wafer is placed on the bias electrode 020. The reaction gas in the plasma treatment process, such as fluorine, is introduced into the reaction chamber 022 through the gas source 012. A specific pressure in the reaction chamber 022 is maintained by the pressure control valve 023 and the vacuum pump 024. The excitation radio-frequency power supply 011 is tuned via the excitation matching network 010, and supplies power to the radio-frequency coils 001 through the three-phase switch 026. Plasma is generated in the reaction chamber 022 through inductive couplings, and the wafer is treated by the plasma treatment process. When the plasma treatment process is completed, an input of radio-frequency power is stopped and an input of the reaction gas in the plasma treatments process is stopped.

When the cleaning process is required, a substrate sheet is placed on the bias electrode 020. The reaction gas in the cleaning process, such as argon, oxygen and nitrogen trifluoride, is introduced into the reaction chamber 022 through the gas source 012. A specific pressure of reaction chamber 022 is maintained by the pressure control valve 023 and the vacuum pump 024. The excitation radio-frequency power supply 011 is tuned via the excitation matching network 010, and supplies the power to the Faraday shielding plate 009 through the three-phase switch 026. The power from the Faraday shielding plate 009 generates argon ions, and the like, which are sputtered to an inner wall of the dielectric window 002 to clean the dielectric window 002. When the cleaning process is completed, the input of radio-frequency power is stopped and an input of the reaction gas in the cleaning process is stopped.

The Faraday shielding apparatus further includes a heating circuit. The heating circuit includes a heating supply power 015, and when the healing circuit is used for the etching process, the Faraday shielding plate 009 is energized and heated.

As illustrated in FIG. 4, an application method specifically lies in the following.

During the etching process, the etching reaction gas is introduced into the reaction chamber 022, the excitation radio-frequency power supply 011 is applied to the radio-frequency coils 001, and plasma is generated to etch the substrate sheet. At the same time, the heating circuit is conductively connected to the Faraday shielding plate 009, increasing the temperature of the Faraday shielding plate 009 when it is energized, heating the dielectric window 002, and reducing the deposition amount of products. In this embodiment, the Faraday shielding plate 009 is integrally sintered in the dielectric window 002 to improve the heating efficiency.

During the cleaning process, the heating circuit and the Faraday shielding plate 009 are turned off. The cleaning reaction gas is introduced into the reaction chamber 022, and the Faraday shielding plate 009 is applied with the shielding power supply so as to clean the dielectric window 002.

During the etching process, the excitation radio-frequency power supply 011 is tuned via the excitation matching network 010, and supplies the power to the radio-frequency coils 001 through the three-phase switch 026. In order to prevent the the couplings between the radio-frequency coils 001 and the Faraday shield 009 from affecting radio frequencies of the radio-frequency coils 001 and heating of the Faraday shielding plate 009, the heating circuit of the present disclosure further includes a filter circuit unit 030. The output terminal of the heating power supply 015 is connected to the Faraday shielding plate 009 after being filtered via the filter circuit unit 030, which effectively preventing generation of couplings between the radio-frequency coils 001 and the Faraday shielding plate 009.

The plasma etching system further includes a feedback control circuit, and the feedback control circuit includes a temperature measurement sensor 016, a temperature controller 013 and a solid state relay 014. The solid state relay 014 is arranged on the heating circuit and configured to control the heating circuit to be turned-on and turned-off; the temperature measurement sensor 016 is configured to measure the temperature of the Faraday shielding plate 009 and transmit data to the temperature controller 013. The temperature controller 013 feeds back signals to control the turn-on and turn-off of the solid state relay 014 according to the set temperature. When the Faraday shielding plate 009 reaches a high temperature set by the temperature controller 013, the temperature controller 013 feeds back the signals to control the circuit to be turned off through the solid state relay 014. When the temperature of the Faraday shielding plate 009 drops below the set low temperature, the temperature measurement sensor 016 detects the drop of the temperature and then transmits data to the temperature controller 013. The temperature controller 013 feeds back the signals again to control the circuit to be turned on for heating through the solid state relay 014 Thus, the feedback control circuit enables the Faraday shield 009 to maintain a proper temperature. For the sake of safety, two sets of the temperature measurement sensors 016 and the temperature controllers 013 can be set to control the solid state relay 014 in parallel, which is capable of preventing control failures and equipment damages due to damages of the temperature measurement sensor 016 or the temperature controller 013. Two sets of the temperature measurement sensors 016 are capable of measuring different positions on the Faraday shielding plate 009 to prevent the temperature of the Faraday shielding plate 009 from being unbalanced and prevent the local temperature of the Faraday shielding plate 009 from being too high or too low.

To prevent the couplings between the feedback control circuit and the radio-frequency coils 001 during the etching process, the filter circuit unit 030 is further arranged on the feedback control circuit.

Specifically, the conductive ring 0092 is connected with the positive pole of the heating circuit, and the outer terminal of each of the conductive petal-shaped members 0091 is connected with a negative pole of the heating circuit; or the conductive ring 0092 is connected with the negative pole of the heating circuit, and the outer terminal of each of the conductive petal-shaped members 0091 is connected with the positive pole of the heating circuit. In this connection mode, each of the conductive petal-shaped members 0091 flows current, and the heating is more balanced and rapid.

Alternatively, a plurality of breaks 0093 are arranged on the conductive ring 0092 to form a plurality of arc segments spaced from and insulated to each other. Each arc segment is connected with a plurality of conductive petal-shaped members 091. he outer terminal of one conductive petal-shaped member 091 on one or more arc segment is connected with the positive pole of the heating circuit. The outer terminal of another conductive petal-shaped member 091 on the arc segment is connected with the negative pole of the heating circuit. The heating current flows in from the outer terminal of one conductive petal-shaped member 0091, flows through a corresponding arc segment, and flows out from the outer terminal of another conductive petal-shaped member 0091.

In order to extend the current flow length to make the heating more balanced, in the one arc segment, the one conductive petal-shaped member 0091 connected with the positive pole of the heating circuit and the other conductive petal-shaped member 0091 connected with the negative pole of the heating circuit are located at both ends of an arc on the arc segment, respectively.

The advantaces of this connection mode are that: the current flow paths on the Faraday shielding plate 009 is few and the distance is shorter, which can reduce the couplings between the Faraday shielding plate 009 and radio-frequency coils 001. In addition, there are fewer terminals, which is convenient for installation, simplifies the equipment structure and saves the equipment space.

In this embodiment, one break 0093 is arranged on the conductive ring 0092 to form an arc segment. In this embodiment, the positions of the wire interfaces are proximate to each other, which is convenient for wiring.

1. A Faraday shielding apparatus which can be used for heating of a plasma etching system, comprising a Faraday shielding plate, and the Faraday shielding plate includes a conductive ring and a plurality of conductive petal-shaped members radially symmetrically connected to an outer periphery of the conductive ring, wherein the Faraday shielding apparatus further includes a heating circuit, and when the heating circuit is used in an etching process, the Faraday shielding plate is heated by electricity.

2. The Faraday shielding apparatus according to claim 1, wherein the heating circuit includes a heating supply power and a filter circuit unit, an output terminal of the heating power supply is connected to the Faraday shielding plate after being filtered via the filter circuit unit.

3. The Faraday shielding apparatus according to claim 2, wherein the Faraday shielding apparatus further includes a feedback control circuit, the feedback control circuit includes a temperature measurement sensor, a temperature controller and a solid state relay; the solid state relay is arranged on the heating circuit and configured to control the heating circuit to be turned on and turned off; the temperature measurement sensor is configured to measure a temperature of the Faraday shielding plate and transmit data to the temperature controller; and the temperature controller feeds back signals to control a turn-on and turn-off of the solid state relay according to a set temperature.

4. The Faraday shielding apparatus according to claim 1, wherein the conductive ring is connected with a positive pole of the heating circuit, and an outer terminal of each of the conductive petal-shaped members is connected with a negative pole of the heating circuit; or
the conductive ring is connected with the negative pole of the heating circuit, and the outer terminal of each of the conductive petal-shaped members is connected with the positive pole of the heating circuit.

5. The Faraday shielding apparatus according to claim 1, wherein the conductive ring includes a plurality of arc segments spaced from and insulated to each other; each arc segment is connected with a plurality of conductive petal-shaped members; the outer terminal of one conductive petal-shaped member on one or more arc segment is connected with the positive pole of the heating circuit; an outer terminal of another conductive petal-shaped member on the arc segment is connected with the negative pole of the heating circuit.

6. The Faraday shielding apparatus according to claim 5, wherein in the one arc segment, the one conductive petal-shaped member connected with the positive pole of the heating circuit and the other conductive petal-shaped member connected with the negative pole of the heating circuit are located at both ends of an arc on the arc segment, respectively.

7. A plasma etching system, wherein the plasma etching system includes the Faraday shielding apparatus which can be used for heating according to claim 1.

8. The plasma etching system according to claim 7, wherein the plasma etching system further includes a dielectric window, and the Faraday shielding plate is integrally sintered in the dielectric window.
